(19) United States
(12) Patent Application Publication
(10) Pub. No.: US 2025/0341556 A1
(43) Pub. Date: Nov. 6, 2025

(54) NOISE DETECTION APPARATUS AND METHOD

(71) Applicants: Hyundai Mobis Co., Ltd., Seoul (KR); University-Industry Cooperation Group of Kyung Hee University, Yongin-si (KR)

(72) Inventors: Seong Sik YOO, Yongin-si (KR); Kwi Hyun KANG, Yongin-si (KR); Na Young LEE, Yongin-si (KR); Jun Seo PARK, Yongin-si (KR); Jin Gyun KIM, Suwon-si (KR); Ji Hyeon LEE, Yongin-si (KR); Hyeon Ah SHIN, Suwon-si (KR); Seung In OH, Bucheon-si (KR); Hyun Woo BAEK, Suwon-si (KR)

(73) Assignees: Hyundai Mobis Co., Ltd., Seoul (KR); University-Industry Cooperation Group of Kyung Hee University, Yongin-si (KR)

(21) Appl. No.: 19/098,124

(22) Filed: Apr. 2, 2025

(30) Foreign Application Priority Data
May 3, 2024 (KR) 10-2024-0059209

(51) Int. Cl. G01R 29/26; G01P 15/18

(52) U.S. Cl. CPC G01R 29/26; G01P 15/18

(57) ABSTRACT

A noise detection apparatus and method therefor are provided. The apparatus includes sensors to detect signals for a test subject, and a processor to calculate signal-to-noise ratios (SNRs) for signals input from the sensors, analyze a frequency spectrum for each of the signals to detect noise, and remove noise from the signals based on at least one of the SNR, a specific signal, or a specific frequency band, or any combination thereof.

### CROSS-REFERENCE TO RELATED APPLICATION

This application claims priority to and the benefit under 35 USC § 119(a) of Korean Patent Application No. 10-2024-0059209, filed on May 3, 2024, in the Korean Intellectual Property Office, the entire disclosures of which is hereby incorporated by reference for all purposes as if set forth herein.

### BACKGROUND

### 1. Field

Exemplary embodiments of the present disclosure relate to a noise detection apparatus and method, which removes noise from signals measured from a plurality of sensors.

### 2. Description of the Related Art

A vehicle is composed of a plurality of components, and each of the components operates organically to enable driving of the vehicle.

Each of the plurality of components provided in the vehicle is tested to check performance thereof in terms of noise and vibration.

The test may be conducted in the form of a coupled model in which each component is coupled to a connector and a jig. The test is conducted by evaluating the performance in terms of noise and vibration by detecting an acceleration response based on signals measured from a plurality of sensors installed on a component or adjacent to the component while the component operates.

To test the performance of a component, it is necessary to select a plurality of sensor signals used to measure data related to the component. The process of selecting signals includes simultaneously measuring a plurality of sensor signals, comparing the magnitude of the signal and noise among the data to determine whether the data is useful, and detecting a useful signal.

A test device may then use the detected signal to predict the performance of the component in terms of noise and vibration.

However, the process of individually comparing a plurality of sensor signals and checking the signal-to-noise ratio (SNR) of a vast amount of data is carried out by humans, which is time-consuming and labor-intensive.

Accordingly, there is a need for a means and method for checking the SNR of a plurality of sensor signals to determine the usefulness of data.

The related art of the present disclosure is disclosed in Korean Patent Application Publication No. 10-2024-0048109 (entitled “LEAK SENSING SYSTEM AND MOTHOD FOR THE SAME”).

### SUMMARY

An objective of the present disclosure is to provide a noise detection apparatus and method, which removes noise by removing a specific frequency band or a specific signal based on a signal-to-noise ratio (SNR) for a plurality of sensor signals.

In a general aspect of the disclosure, a noise detection apparatus includes: a plurality of sensors configured to detect signals for a test subject; and a processor configured to calculate signal-to-noise ratios (SNRs) for a plurality of signals input from the plurality of sensors, analyze a frequency spectrum for each signal of the plurality of signals to detect noise, and remove noise from the plurality of signals based on at least one of the SNR, a specific signal, or a specific frequency band, or any combination thereof.

In response to a reference SNR being set, the processor may be further configured to remove noise by batch deleting a range where an SNR is lower than the reference SNR from the plurality of signals.

In response to the specific signal being selected, the processor may be further configured to remove noise by deleting a signal range corresponding to the specific signal from the plurality of signals.

In response to the specific frequency band being selected, the processor may be further configured to remove noise by deleting a frequency range corresponding to the specific frequency band from the plurality of signals.

The processor may be further configured to detect a signal with an SNR lower than a set value for the plurality of signals, and perform control to change a location of a sensor, among the plurality of sensors, corresponding to the signal.

The plurality of sensors may be installed on the test object or at a location adjacent to the test object, wherein the plurality of sensors may input acceleration signals along the x-axis, y-axis, and z-axis of the test object to the processor.

The processor may be further configured to quantitatively compare the signals received from the plurality of sensors.

The processor may be further configured to selectively filter the signals for each frequency band.

The processor may be further configured to selectively filter the signals based on whether the signals satisfy a reference value.

In another general aspect of the disclosure, a method for noise detection, includes: analyzing, by a processor, a plurality of signals input from a plurality of sensors in response to signals for a test object being input to the processor from the plurality of sensors; calculating, by the processor, SNRs for the plurality of signals; analyzing, by the processor, a frequency spectrum for each signal of the plurality of signals; detecting, by the processor, noise from the plurality of signals; and removing, by the processor, noise from the plurality of signals based on at least one of the SNR, a specific signal, or a specific frequency band, or any combination thereof.

In the removing of noise, the processor may be configured to set a reference SNR based on the input data, and batch delete a range where an SNR is lower than the reference SNR from the plurality of signals.

In the removing of noise, in response to a specific signal being selected based on the input data, the processor may be configured to delete a signal range corresponding to the specific signal from the plurality of signals, and in response to a specific frequency band being selected, delete a frequency range corresponding to the specific frequency band from the plurality of signals.

The analyzing may include detecting a signal with an SNR lower than a set value for the plurality of signals, and performing control to change a location of a sensor, among the plurality of the sensor, corresponding to the signal.

The method may further include quantitatively comparing the signals received from the plurality of sensors.

The method may further include selectively filtering the signals for each frequency band.

The method may further include selectively filtering the signals based on whether the signals satisfy a reference value.

According to an aspect of the present disclosure, the noise detection apparatus and method of the present disclosure may detect and easily remove specific noise from a plurality of signals input from a plurality of sensors.

According to an aspect of the present disclosure, the noise detection apparatus and method of the present disclosure may list and quantitatively compare signals received from a plurality of sensors, and may selectively filter the signals for each frequency band or based on a required condition.

According to an aspect of the present disclosure, the noise detection apparatus and method of the present disclosure may easily and quickly determine the usefulness of response data from an acceleration sensor.

According to an aspect of the present disclosure, the noise detection apparatus and method of the present disclosure may check the status of a plurality of sensors based on an SNR, and may optimize the locations of the sensors.

### BRIEF DESCRIPTION OF THE DRAWINGS

FIG. 1 is a block diagram schematically illustrating a configuration of a noise detection apparatus including a plurality of sensors according to an embodiment of the present disclosure.

FIG. 2 is a block diagram schematically illustrating a configuration of the noise detection apparatus according to an embodiment of the present disclosure.

FIG. 3 is a view illustrating acceleration signals from sensors according to an embodiment of the present disclosure.

FIG. 4 is a view illustrating the signal-to-noise ratio (SNR) of sensor signals according to an embodiment of the present disclosure.

FIGS. 5A and 5B are views illustrating the frequency spectrum and SNR for a plurality of sensors according to an embodiment of the present disclosure.

FIGS. 6A and 6B are views illustrating the frequency spectrum and SNR regarding batch noise removal according to an embodiment of the present disclosure.

FIGS. 7A to 7C are views illustrating the frequency spectrum and SNR regarding selective noise removal according to an embodiment of the present disclosure.

FIGS. 8A to 8C are views illustrating the SNR regarding selective noise removal according to an embodiment of the present disclosure.

FIG. 9 is a flowchart illustrating a noise detection method using the noise detection apparatus according to an embodiment of the present disclosure.

### DETAILED DESCRIPTION

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Hereinafter, with reference to the accompanying drawings, embodiments of the present disclosure will be described in detail so that a person skilled in the art can readily carry out the present disclosure. However, the present disclosure may be embodied in many different forms and is not limited to the embodiments described herein.

In the following description of the embodiments of the present disclosure, a detailed description of known functions and configurations incorporated herein will be omitted when it may make the subject matter of the present disclosure rather unclear. Parts not related to the description of the present disclosure in the drawings are omitted, and like parts are denoted by similar reference numerals.

In the present disclosure, components that are distinguished from each other are intended to clearly illustrate each feature. However, it does not necessarily mean that the components are separate. That is, a plurality of components may be integrated into one hardware or software unit, or a single component may be distributed into a plurality of hardware or software units. Thus, unless otherwise noted, such integrated or distributed embodiments are also included within the scope of the present disclosure.

In the present disclosure, components described in the various embodiments are not necessarily essential components, and some may be optional components. Accordingly, embodiments consisting of a subset of the components described in one embodiment are also included within the scope of the present disclosure. In addition, embodiments that include other components in addition to the components described in the various embodiments are also included in the scope of the present disclosure.

Hereinafter, with reference to the accompanying drawings, embodiments of the present disclosure will be described in detail so that a person skilled in the art can readily carry out the present disclosure. However, the present disclosure may be embodied in many different forms and is not limited to the embodiments described herein.

In the following description of the embodiments of the present disclosure, a detailed description of known functions and configurations incorporated herein will be omitted when it may make the subject matter of the present disclosure rather unclear. Parts not related to the description of the present disclosure in the drawings are omitted, and like parts are denoted by similar reference numerals.

In the present disclosure, when a component is referred to as being “linked,” “coupled,” or “connected” to another component, it is understood that not only a direct connection relationship but also an indirect connection relationship through an intermediate component may also be included. In addition, when a component is referred to as “comprising” or “having” another component, it may mean further inclusion of another component not the exclusion thereof, unless explicitly described to the contrary.

In the present disclosure, the terms first, second, etc. are used only for the purpose of distinguishing one component from another, and do not limit the order or importance of components, etc., unless specifically stated otherwise. Thus, within the scope of this disclosure, a first component in one exemplary embodiment may be referred to as a second component in another embodiment, and similarly a second component in one exemplary embodiment may be referred to as a first component.

In the present disclosure, components that are distinguished from each other are intended to clearly illustrate each feature. However, it does not necessarily mean that the components are separate. That is, a plurality of components may be integrated into one hardware or software unit, or a single component may be distributed into a plurality of hardware or software units. Thus, unless otherwise noted, such integrated or distributed embodiments are also included within the scope of the present disclosure.

In the present disclosure, components described in the various embodiments are not necessarily essential components, and some may be optional components. Accordingly, embodiments consisting of a subset of the components described in one embodiment are also included within the scope of the present disclosure. In addition, exemplary embodiments that include other components in addition to the components described in the various embodiments are also included in the scope of the present disclosure.

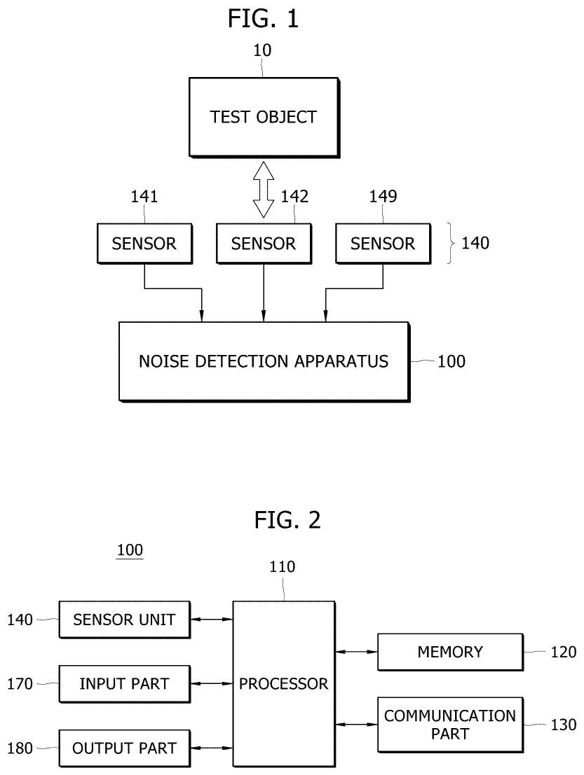

FIG. 1 is a block diagram schematically illustrating a configuration of a noise detection apparatus including a plurality of sensors according to an embodiment of the present disclosure.

Referring to FIG. 1, a noise detection apparatus 100 according to the present embodiment detects, through a plurality of sensor units 140, noise and vibration generated during operation of a test object 10, with the test object 10 being a component put into a vehicle. In this case, one of the methods for predicting the performance of the test object 10 is to calculate a black force for the test object 10.

Based on detected signals, a test device (not illustrated) may predict the performance of each component by analyzing the black force, which is a model that converts the vibration of the test object 10 during its operation into force at a coupling point.

The test device may apply the black force to the Frequency Response Function Based Sub-structuring (FBS) to predict the final performance in the final coupled model. To calculate the black force, noise responses from a plurality of sensors are required.

The test device may conduct a test by either increasing a driving force of a component relative to noise or reducing noise relative to the driving force. Increasing the driving force is generally not feasible, and thus the test device may conduct the test by reducing noise.

To calculate the black force, it is necessary to reduce noise by selecting a highly useful signal from a plurality of sensor signals. Accordingly, the noise detection apparatus 100 may calculate a signal-to-noise ratio (SNR) and perform control to ensure that the value is equal to or lower than a reference value. In this case, if the SNR does not satisfy a set value lower than the reference value, a sensor location may be rearranged.

The noise detection apparatus 100 may analyze signals input from the plurality of sensors to select highly useful data and apply the data to the test device. Accordingly, the test device may determine or predict the performance of the test object 10 in terms of noise and vibration based on the filtered signals.

A plurality of sensors 141 to 149 may be installed on a component that is the test object 10, or may be installed at a location adjacent to the test object 10. The plurality of sensors 141 to 149 may detect acceleration signals along the x-axis, y-axis, and z-axis for the test object 10.

The test object 10 may be an electric power steering apparatus, a compressor, or the like, which is mounted on a connector such as a bush or a receiver such as a jig.

The plurality of sensors 141 to 149 detect noise and vibration while the test object 10 is operating, as well as noise while the test object 10 is not operating, and input the detected noise and vibration to the noise detection apparatus 100.

The noise detection apparatus 100 lists the signals input from the plurality of sensors 141 to 149 and analyzes the frequency spectrum and the SNR. The noise detection apparatus 100 may select signals based on the SNR. The SNR is calculated based on a value obtained by dividing signal magnitude Ps by noise magnitude Pn, and may indicate relative signal magnitude by determining signal strength relative to noise.

The noise detection apparatus 100 may detect noise contained in a signal, and either control the signal containing the noise or remove a frequency band corresponding to the noise.

The noise detection apparatus 100 may list and compare all data in the form of an “absolute value graph” and an “SNR graph” corresponding to a plurality of sensor signals, and may determine the magnitude of each signal and the influence of noise. The noise detection apparatus 100 may determine, for each signal or for each frequency band, whether a signal is useful.

During the signal analysis process, the noise detection apparatus 100 may optimize a sensor location by changing the sensor location in real time. If an SNR does not satisfy a set condition, the noise detection apparatus 100 may change the sensor location for the relevant signal to optimize the sensor location based on whether the SNR changes.

The noise detection apparatus 100 may select a signal with an SNR equal to or higher than a set SNR. If the SNR of a specific signal does not satisfy a set condition, the noise detection apparatus 100 may delete the signal. The noise detection apparatus 100 may select, through filtering, a signal with an SNR equal to or higher than a certain value, thereby enabling accurate noise analysis and improving data quality.

The noise detection apparatus 100 of the present disclosure may provide high-quality data for virtual component coupling performance verification for dynamic sub-structuring, thereby improving signal processing efficiency and data consistency.

The noise detection apparatus 100 may be used in an evaluation method (e.g., MODAL, ODS, BF-TPA, etc.) that simultaneously measures a plurality of sensors for noise analysis of a test object (e.g., a vehicle component).

In some cases, the noise detection apparatus 100 may be included in a test device.

FIG. 2 is a block diagram schematically illustrating a configuration of the noise detection apparatus according to an embodiment of the present disclosure.

Referring to FIG. 2, the noise detection apparatus 100 may include a communication part 130, a memory 120, the sensor unit 140, an input part 170, an output part 180, and a processor 110.

The sensor unit 140 may include the plurality of sensors 141 to 149. The sensor unit 140 may be installed on the test object 10, or may be installed at a location adjacent to the test object 10. The sensor unit 140 may measure noise or vibration for the test object 10 and input the measured noise or vibration to the processor 110. The sensor unit 140 may input acceleration signals along three axes of the test object 10 to the processor 110.

The input part 170 may input setting data for signal analysis and noise detection, and condition data for signal filtering. The input part 170 may include at least one of the following input means: a button; a switch; and a touchpad.

For example, the input part 170 may receive input of at least one of the followings: a filtered signal; a reference value of an SNR (reference SNR) for filtering; a signal to be filtered; and a frequency band.

The output part 180 may include at least one of the following output means: a speaker; a display; and an operating lamp. The output part 180 may output a status based on noise detection in response to a control command from the processor 110. The output part 180 may output a graph of the frequency spectrum or SNR of sensor signals.

The output part 180 may output data regarding the signal filtered as a result of the noise detection in response to a control command from the processor 110, in at least one of the following forms: a sound effect; warning tone; and voice guidance. The output part 180 may output an guidance message, a warning message, or a warning light.

The communication part 130 includes a wired or wireless communication module to communicate. The communication part 130 may input signals from the plurality of sensors 141 to 149 to the processor 110 in response to a control command from the processor 110. The communication part 130 may also convert signals received from the plurality of sensors 141 to 149 into a certain form.

The communication part 130 may communicate using Wi-Fi, Ethernet, Bluetooth, mobile communication (5G, LTE, CDMA, and GSM), short-range wireless communication, serial communication, parallel communication, power line communication, and the like.

The memory 120 may store data on at least one of the followings: the plurality of sensors 141 to 149; installation locations of the plurality of sensors 141 to 149; acceleration signals received from the plurality of sensors 141 to 149; frequency spectrum; and SNR of the signals.

The memory 120 may store data on at least one of the followings: a signal analysis algorithm; a noise detection algorithm; an SNR computation algorithm; a signal filtering algorithm; and a noise removal algorithm.

The memory 120 may include storage media such as random access memory (RAM), non-volatile memory such as read-only memory (ROM) and electrically erased programmable ROM (EEPROM), flash memory, HDD, SSD, and SDS.

The processor 110 may include at least one microprocessor, and may operate based on data stored in the memory 120.

The processor 110 may analyze the signals input through the plurality of sensors 141 to 149 to generate a frequency spectrum and calculate an SNR. The processor 110 may set a signal or frequency band to be filtered based on the frequency spectrum and the SNR.

The processor 110 may delete a signal range for a signal selected from a plurality of signals or a frequency range for a selected frequency band.

In addition, based on a set reference SNR, the processor 110 may batch delete signals equal to or lower than the set reference SNR. The processor 110 may use a filter to delete a specific range from the plurality of signals.

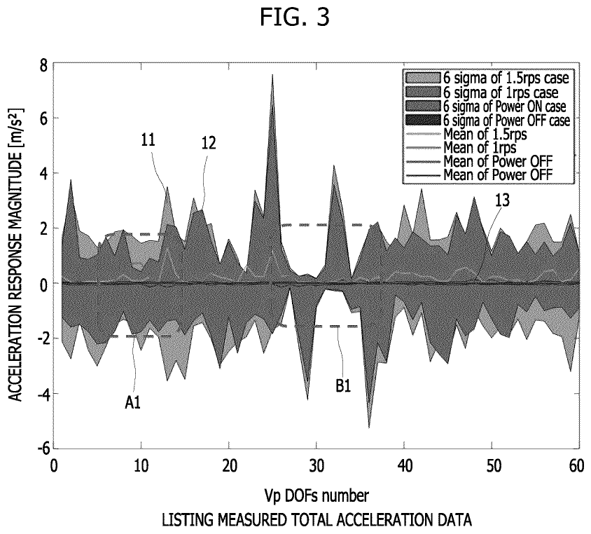

FIG. 3 is a view illustrating acceleration signals from sensors according to an embodiment of the present disclosure.

Referring to FIG. 3, the processor 110 receives and processes acceleration signals input from the plurality of sensors 141 to 149.

The acceleration signals are used to determine the performance of the test object 10, and the processor 110 may remove noise from the plurality of signals (acceleration signals) to select a signal that is highly useful as data. The processor 110 may determine the usefulness of a signal based on the ratio of the signal magnitude to the noise magnitude, i.e., the SNR.

The processor 110 may compare and analyze the magnitude of the signal and noise for when the absolute magnitude of the signal is small and the magnitude of the noise is also small, or for when the absolute magnitude of the signal is great and the magnitude of the noise is great. In this case, the magnitude of the noise may be determined as a ratio relative to the magnitude of the signal. The magnitude of the noise may be determined to be great if the magnitude of the noise is equal to or greater than a first ratio based on the maximum magnitude of the signal; and the magnitude of the noise may be determined to be small if the magnitude of the noise is smaller than a second ratio, which is lower than the first ratio. The first ratio and the second ratio may vary depending on the setting.

The processor 110 may list the absolute response magnitude of all signals and perform an initial comparison and analysis of the absolute magnitude of each signal.

The processor 110 may list and present the acceleration response magnitude for the total acceleration signals input from the plurality of sensors. The processor 110 may analyze a first segment A1 and a second segment B1 with respect to the signal magnitude. In this case, it may be observed that a first signal 11 has greater magnitude than a second signal 12, and that noise 13 has smaller magnitude than the first signal 11 and the second signal 12.

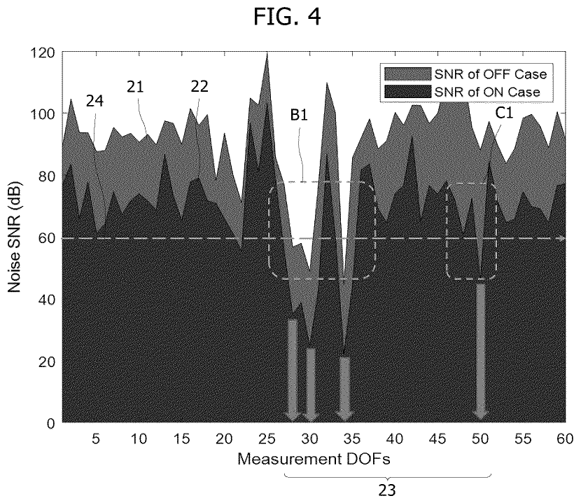

The processor 110 may presume that there is an abnormality in the first segment A1 and the second segment B1 due to significant fluctuations in the acceleration response magnitude of the first segment A1 and the second segment B1. However, the absolute magnitude of the signal alone may not determine the usefulness of the signal, and thus the processor 110 may analyze the signal by calculating an SNR as shown in FIG. 4, which will be described below.

FIG. 4 is a view illustrating the signal-to-noise ratio (SNR) of sensor signals according to an embodiment of the present disclosure.

Referring to FIG. 4, the processor 110 may generate a graph by calculating the SNR for a plurality of signals.

The processor 110 may set the magnitude of the signals Ps, measured from the sensors while the test object 10 is not operating, as noise, and calculate the SNR based on the magnitude of the signals Ps and the magnitude of the noise Pn measured from the sensors while the test object 10 is operating.

Based on the graph of the SNR, the processor 110 may compare the signal magnitude Ps with the noise magnitude Pn while the test object 10 is operating and compare the difference for each sensor.

The processor 110 may compare a first SNR 21 of the first signal 11 input from a first sensor 141 and a second SNR 22 of the second signal 12 input from a second sensor 142. The processor 110 may compare the first SNR 21 and the second SNR 22 based on a reference value 24 for signal quality. In this case, the reference value 24 of the SNR is set to approximately 60 dB, which is just an example, but may vary. The reference value may vary depending on the required condition for determining the usefulness of the signal.

The processor 110 may determine that there is an abnormality in the first SNR 21 of the first signal 11 and the second SNR 22 of the second signal 12 for the second segment B1 where the SNR becomes lower than the reference value 24. In addition, the processor 110 may determine that there is an abnormality in the second SNR 22 for a third segment C1 where the SNR becomes lower than the reference value 24.

That is, the processor 110 may presume that there is an abnormality in the first segment A1 and the second segment B1 based on the signal magnitude in FIG. 3 above, but may determine, based on a result of the SNR analysis, that the first segment A1 is normal and there is an abnormality in the second segment B1. In addition, the processor 110 may detect an abnormality in the third segment C1, which has not been expected from the magnitude comparison.

Accordingly, the processor 110 may analyze the SNR rather than the absolute magnitude of the signals to determine the usefulness as the data for the plurality of signals input from the plurality of sensors.

The processor 110 may set a reference value for the SNR and filter out, from the signals, a signal with the SNR lower than the reference value, a specific signal, or a specific frequency band.

In addition, the processor 110 may detect signals 23 with the SNR that does not satisfy a reference value (required condition) and perform further analysis.

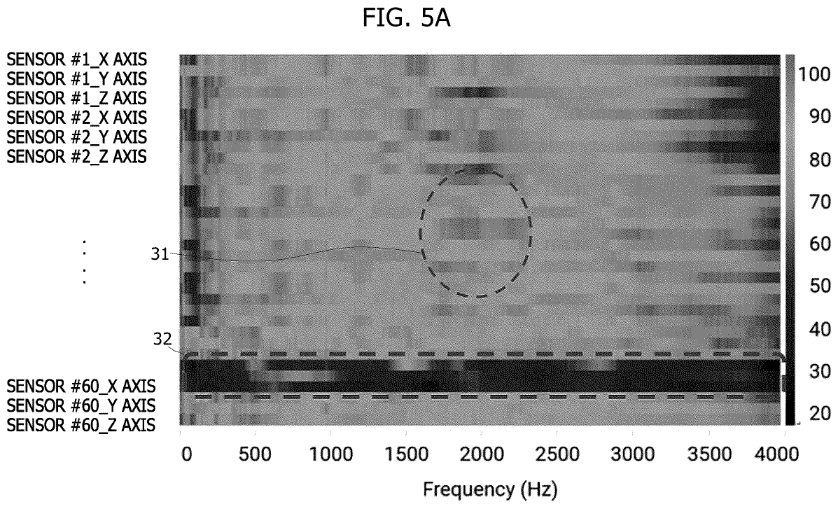

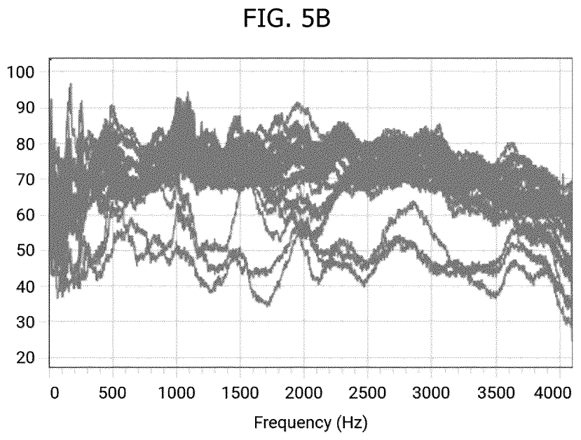

FIGS. 5A and 5B are views illustrating the frequency spectrum and SNR for a plurality of sensors according to an embodiment of the present disclosure.

Referring to FIG. 5A, the processor 110 may detect noise from signals input from the plurality of sensors 141 to 149.

The processor 110 may calculate the SNR for the entire signals input from the plurality of sensors 141 to 149 and analyze the signals for each signal or for each frequency band. The processor 110 may generate a frequency spectrum for each signal and compare the generated frequency spectra with one another.

The processor 110 may sequentially list and analyze a spectrum for each frequency of the x-axis, y-axis, and z-axis of the first sensor 141, a spectrum for each frequency of the x-axis, y-axis, and z-axis of the second sensor 142, and a spectrum for each frequency of the x-axis, y-axis, and z-axis of the Nth sensor 149.

The processor 110 may present the SNR for the plurality of sensors 141 to 149 in color. The processor 110 may compare low and high SNR sections in color. In this case, a first range 31 is a range with a high SNR, and a second range 32 is a range with the lowest SNR among all sensors.

For example, the first range 31 may correspond to the y-axis signal of a 21st sensor, and the x-axis, y-axis, and z-axis signals of a 25th sensor, and may exhibit the highest SNR of approximately 90 dB in a frequency band of 1500 Hz to 2300 Hz. In addition, it may be observed in the second range 32 that the x-axis, y-axis, and z-axis signals of a 59th sensor have the lowest values in the entire frequency band.

The processor 110 may perform analysis for each signal and for each frequency range, and if a signal from a specific sensor does not satisfy a set value for the SNR, the processor 110 may perform control to change a location of the sensor. The processor 110 may generate a guidance or warning regarding a change in the sensor location and output the generated guidance or warning through the output part 180.

When the sensor location changes, the processor 110 may repeat the SNR analysis to optimize the sensor location. When the optimization of the sensor location is completed, if the SNR of a signal is lower than a reference value (reference SNR), the processor 110 may filter out the signal.

The processor 110 may select signals that have a segment with the SNR lower than the reference value (reference SNR). For the selected signals, the processor 110 may batch delete signals in a frequency band where the SNR is lower than the reference value.

In addition, the processor 110 may select a specific signal, or selectively delete signals in a specific frequency band. For example, the processor 110 may batch delete signals corresponding to the second range 32. In addition, the processor 110 may batch delete signals in a low frequency band or a high frequency band from the plurality of signals. That is, the processor 110 may batch delete signals along the x-axis, y-axis, and z-axis of the 59th sensor included in the second range 32.

While deleting the signal of the abnormal sensor, the processor 110 may change a location of the sensor to check whether the SNR improves and check for the abnormality of the sensor. In this way, the processor 110 may calculate the SNRs for signals input from the plurality of sensors and compare the difference for each signal or for each frequency band.

Referring to FIG. 5B, the processor 110 may generate a graph for the SNRs for signals from the plurality of sensors and compare the SNRs.

The processor 110 may check for a change in the magnitude of the SNR for each frequency band. The processor 110 may filter out a signal with the SNR lower than a reference value.

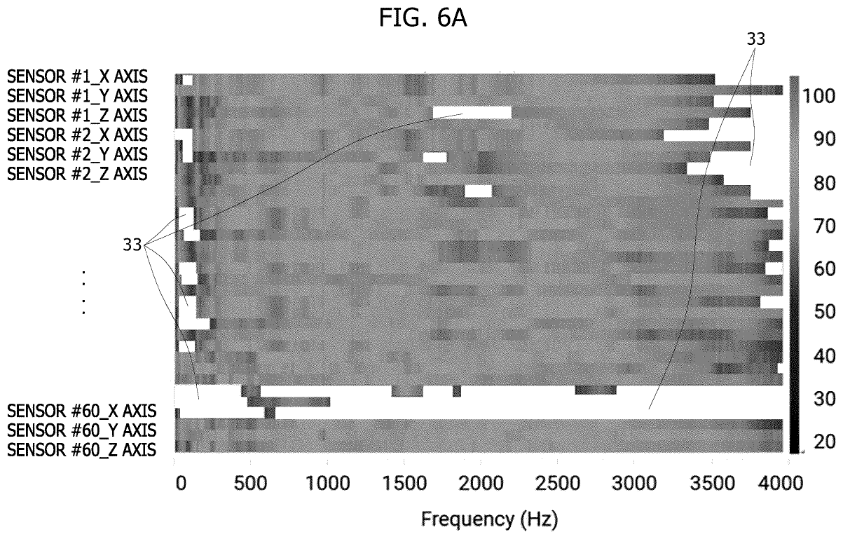

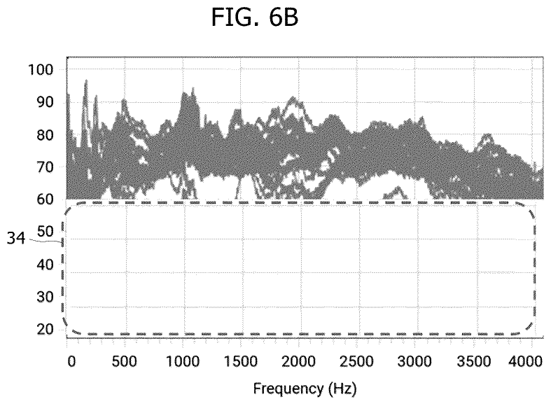

FIGS. 6A and 6B are views illustrating the frequency spectrum and SNR regarding batch noise removal according to an embodiment of the present disclosure.

Referring to FIG. 6A, the processor 110 may perform a task to utilize the sensor signals as actual data by comparing and analyzing the SNRs. The processor 110 may filter the signals, based on the SNR, from the plurality of signals input from the plurality of sensors.

The processor 110 may select a range in the frequency spectrum where the SNR is lower than a reference value and delete a signal and a frequency band in the range. For example, the processor 110 may batch delete signals and frequency bands 33 where the SNR is lower than the reference value.

In this case, the processor 110 may not delete an entirety of a single signal, but may delete only a portion of the signal where the SNR is lower than the reference value. For example, the processor 110 may delete the 50 to 100 Hz band of a first signal, the 0 to 200 Hz and 2000 to 2500 Hz bands of a fifth signal, and the 0 to 450 Hz, 550 to 1500 Hz, and 2000 to 3000 Hz bands of a 59th signal.

By deleting signal and frequency segments for a specific SNR, the processor 110 may batch delete a range 34 where the SNR is lower than a reference value, as shown in FIG. 6B.

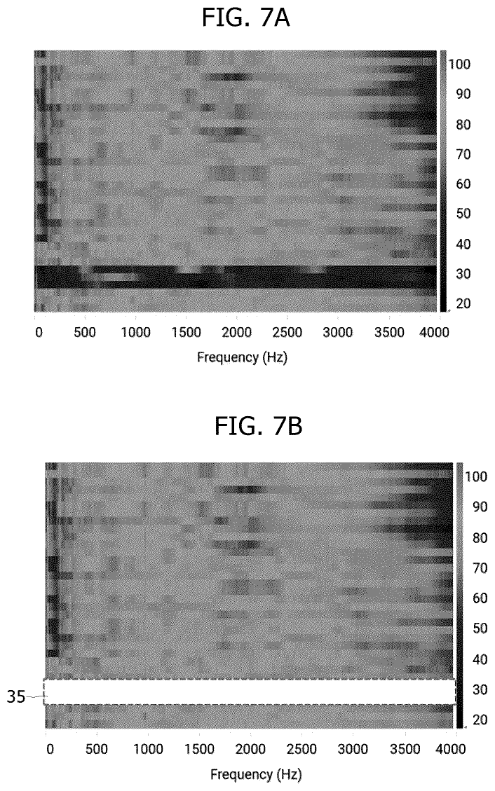

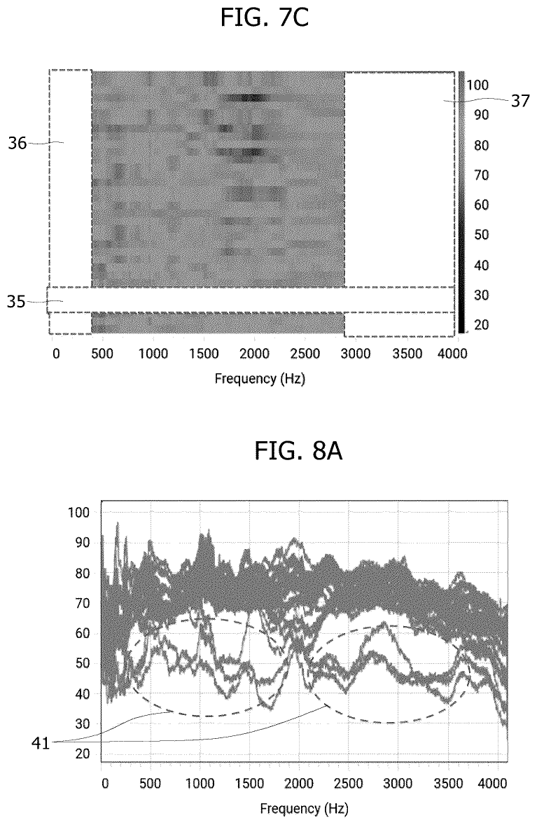

FIGS. 7A to 7C are views illustrating the frequency spectrum and SNR regarding selective noise removal according to an embodiment of the present disclosure.

The processor 110 may delete a specific signal or a signal in a specific frequency band based on data input through the input part 170.

As shown in FIG. 7A, the processor 110 may generate a frequency spectrum for the plurality of sensors 141 to 149 and output the generated frequency spectrum through the output part 180.

When a reference value for the SNR is input through the input part 170, the processor 110 may select a frequency band of a signal with the SNR lower than the reference value and present the selected frequency band on a screen.

When a specific signal is selected through the input part 170, the processor 110 may delete a signal range 35 corresponding to the selected signal, as shown in FIG. 7B.

In addition, when a specific frequency band is selected as shown in FIG. 7C, the processor 110 may delete a frequency range corresponding to the selected frequency band for the entire signal. For example, the processor 110 may delete a frequency range 36 corresponding to the 0 to 400 Hz frequency band and a frequency range 37 corresponding to the 3000 to 4000 Hz frequency band.

The processor 110 may delete the designated frequency ranges 36 and 37 for the entire signal.

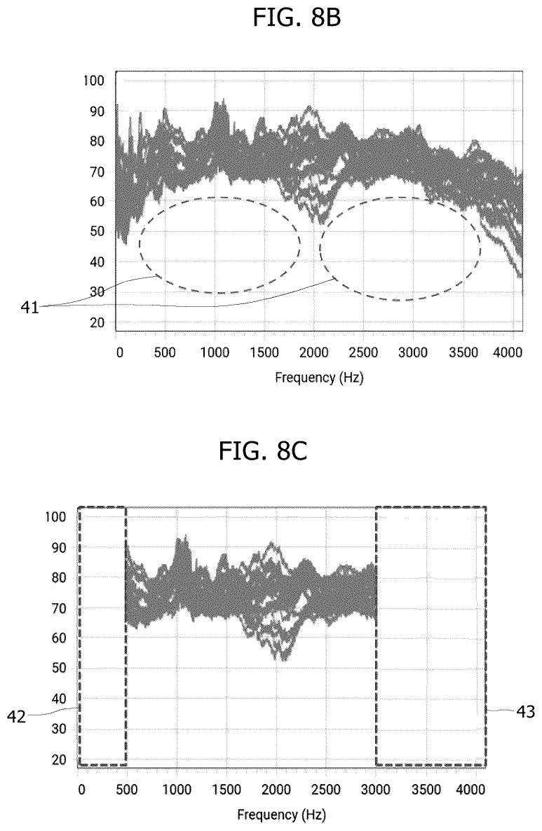

FIGS. 8A to 8C are views illustrating the SNR regarding selective noise removal according to an embodiment of the present disclosure.

The processor 110 may delete a specific signal or a specific frequency band. Graphs of the SNR therefor are illustrated in FIGS. 8A to 8C.

When the processor 110 deletes a specific signal from a graph of the SNR for the plurality of signals as shown in FIG. 8A, the processor 110 may delete a graph of the SNR corresponding to a relevant signal 41 as shown in FIG. 8B

In addition, when deleting a specific frequency band, the processor 110 may delete ranges corresponding to relevant frequency bands 42 and 43 from all signals as shown in FIG. 8C That is, the processor 110 may batch delete signal values in a range where the SNR is lower than a designated value based on the SNR, and may delete a signal range for a signal selected from the plurality of signals or delete a frequency range corresponding to a designated frequency band for the plurality of signals.

Based on a distribution of the SNR, the processor 110 may remove noise based on at least one of an SNR, a signal, and a frequency band.

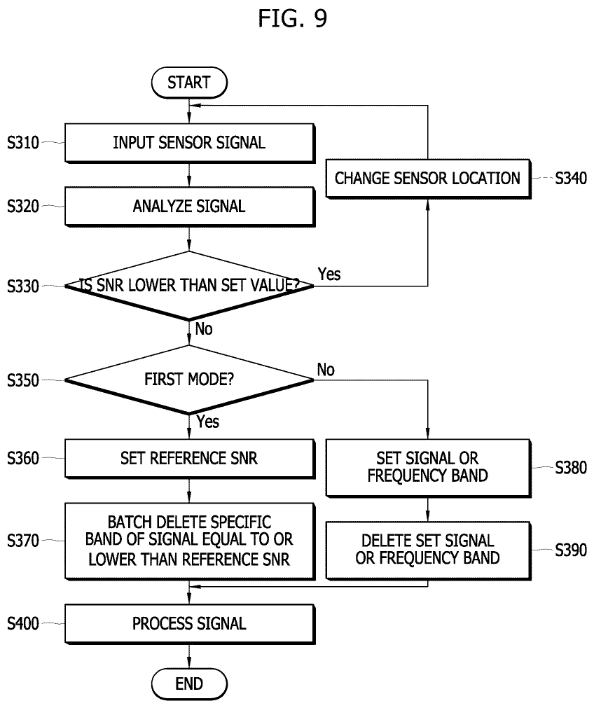

FIG. 9 is a flowchart illustrating a noise detection method using the noise detection apparatus according to an embodiment of the present disclosure.

Referring to FIG. 9, the noise detection apparatus 100 may detect noise by analyzing the SNR for signals input from the plurality of sensors 141 to 149, and remove the noise. The noise detection apparatus may remove noise based on at least one of an SNR, a signal, and a frequency band.

The processor 110 receives signals (acceleration signals) for the test object 10 from the plurality of sensors 141 to 149 (S310).

The processor 110 analyzes the plurality of signals to calculate the SNR (S320).

The processor 110 determines whether a signal with an SNR lower than a set value is present (S330), and detects a signal with the SNR lower than the set value and performs control to change a location of the sensor (S340).

After the sensor location is changed, the processor 110 calculates the SNR of the signal input from the sensor and again determines whether the SNR is lower than the set value. If the SNR is lower than the set value, the processor 110 again perform control to change the sensor location.

In this way, the processor 110 may optimize the sensor location by repeating the change of the sensor location for a signal with an SNR lower than a set value.

In some cases, before performing a test on the test object 10, the processor 110 may first perform the sensor location optimization, and then detect noise from the sensor when the optimization is completed.

The processor 110 may determine that a sensor, which has an SNR lower than the set value even after changing the sensor location a certain number of times, is faulty, and perform an inspection for sensor failure.

The processor 110 may set a noise removal mode based on a distribution of the SNR of the plurality of signals if the SNR of the input signal is equal to or higher than a set value.

When a reference SNR (reference value) is input through the input part 170, the processor 110 may determine that the noise removal mode is in a first mode (S350).

The processor 110 sets a reference SNR based on the data input through the input part 170 (S360). In this case, the reference SNR may be set to a value higher than the set value.

The processor 110 detects a signal or frequency band with an SNR lower than the reference SNR for the plurality of signals.

The processor 110 batch deletes signals, among the plurality of signals, in a range where the SNR is lower than the reference SNR (S370). A portion of a single signal may be deleted for each frequency band as shown in FIGS. 6A and 6B described above.

When a specific signal or a specific frequency band is input through the input part 170, the processor 110 may set a second mode of the noise removal mode.

The processor 110 sets the specific signal or the specific frequency band, input through the input part 170, to be deleted (S380).

The processor 110 may delete the specific signal set from the plurality of signals. The processor 110 may delete the designated signal range 35, as shown in FIG. 7B described above.

In addition, the processor 110 may delete all of the frequency ranges set for the plurality of signals. The processor 110 may delete the designated frequency range 36 and 37 as shown in FIG. 7C described above.

The processor 110 may remove noise from the plurality of signals based on at least one of an SNR, a signal, and a frequency band, thereby improving signal quality.

The processor 110 processes and outputs the filtered signal (S400).

The noise detection apparatus 100 may transmit the filtered signal to the test device. Accordingly, the test device may predict performance of the test object 10 based on the filtered signal.

Therefore, the noise detection apparatus and method according to an aspect of the present disclosure may easily distinguish a sensor with an abnormality, improve the reliability of the filtered signal by deleting a range or signal with a low SNR, and improve the accuracy of the determination result due to reduced noise.

What is claimed is:

1. A noise detection apparatus comprising:
a plurality of sensors configured to detect signals for a test subject; and
a processor configured to:
calculate signal-to-noise ratios (SNRs) for a plurality of signals input from the plurality of sensors;
analyze a frequency spectrum for each signal of the plurality of signals to detect noise; and
remove noise from the plurality of signals based on at least one of the SNR, a specific signal, or a specific frequency band, or any combination thereof.

2. The noise detection apparatus of claim 1, wherein, in response to a reference SNR being set, the processor is further configured to remove noise by batch deleting a range where an SNR is lower than the reference SNR from the plurality of signals.

3. The noise detection apparatus of claim 1, wherein, in response to the specific signal being selected, the processor is further configured to remove noise by deleting a signal range corresponding to the specific signal from the plurality of signals.

4. The noise detection apparatus of claim 1, wherein, in response to the specific frequency band being selected, the processor is further configured to remove noise by deleting a frequency range corresponding to the specific frequency band from the plurality of signals.

5. The noise detection apparatus of claim 1, wherein the processor is further configured to:
detect a signal with an SNR lower than a set value for the plurality of signals; and
perform control to change a location of a sensor, among the plurality of sensors, corresponding to the signal.

6. The noise detection apparatus of claim 1, wherein the plurality of sensors are installed on the test object or at a location adjacent to the test object, and
wherein the plurality of sensors input acceleration signals along the x-axis, y-axis, and z-axis of the test object to the processor.

7. The noise detection apparatus of claim 1, wherein the processor is further configured to quantitatively compare the signals received from the plurality of sensors.

8. The noise detection apparatus of claim 7, wherein the processor is further configured to selectively filter the signals for each frequency band.

9. The noise detection apparatus of claim 7, wherein the processor is further configured to selectively filter the signals based on whether the signals satisfy a reference value.

10. A method for noise detection, the method comprising:
analyzing, by a processor, a plurality of signals input from a plurality of sensors in response to signals for a test object being input to the processor from the plurality of sensors;
calculating, by the processor, SNRs for the plurality of signals;
analyzing, by the processor, a frequency spectrum for each signal of the plurality of signals;
detecting, by the processor, noise from the plurality of signals; and
removing, by the processor, noise from the plurality of signals based on at least one of the SNR, a specific signal, or a specific frequency band, or any combination thereof.

11. The method of claim 10, wherein in the removing of noise, the processor is configured to:
set a reference SNR based on the input data; and
batch delete a range where an SNR is lower than the reference SNR from the plurality of signals.

12. The method of claim 10, wherein in the removing of noise, in response to a specific signal being selected based on the input data, the processor is configured to:
delete a signal range corresponding to the specific signal from the plurality of signals; and
in response to a specific frequency band being selected, delete a frequency range corresponding to the specific frequency band from the plurality of signals.

13. The method of claim 10, wherein the analyzing comprises:
detecting a signal with an SNR lower than a set value for the plurality of signals; and
performing control to change a location of a sensor, among the plurality of the sensor, corresponding to the signal.

14. The method of claim 10, further comprising:
quantitatively comparing the signals received from the plurality of sensors.

15. The method of claim 14, further comprising:
selectively filtering the signals for each frequency band.

16. The method of claim 14, further comprising:
selectively filtering the signals based on whether the signals satisfy a reference value.
